(19) United States
(12) Patent Application Publication
(10) Pub. No.: US 2026/0132510 A1
(43) Pub. Date: May 14, 2026

(54) LEAKAGE MINIMIZING PULSE VALVE MANIFOLD

(71) Applicant: ASM IP Holding B.V., Almere (NL)

(72) Inventors: Allen D'Ambra, Phoenix, AZ (US); Sheshraj Tulshibagwale, Chandler, AZ (US); Dinkar Nandwana, Chandler, AZ (US); Christopher Falcone, Chandler, AZ (US); Vishnu Shakti, Bangalore (IN); Kudakwashe Faith Nhanga, Phoenix, AZ (US)

(21) Appl. No.: 19/382,726

(22) Filed: Nov. 7, 2025

Related U.S. Application Data
(60) Provisional application No. 63/718,129, filed on Nov. 8, 2024.

(51) Int. Cl. C23C 16/455

(52) U.S. Cl. CPC C23C 16/45561; C23C 16/45565

(57) ABSTRACT

A pulse valve manifold (PVM) assembly includes a PVM. The PVM is formed from two or less manifold parts. The PVM includes a pipe section having an entry inlet to enable a reactant to enter the PVM, a rectangular block section having a top surface and a bottom surface, wherein the top surface is connected to the pipe section, and a base section connected to the bottom surface having an outlet to flow the reactant gas out to a showerhead. A single part PVM may be formed using additive manufacturing (such as 3D printing). Alternatively, a two-part PVM may be formed having a top section including the pipe section and a bottom section including the base. The PVM further includes a wetted path that flows a reactant gas from the entry inlet to the outlet, and the wetted path may include a helical section.

### CROSS-REFERENCE TO RELATED APPLICATIONS

This application claims priority to U.S. Provisional Patent Application Ser. No. 63/718,129 filed Nov. 8, 2024 titled LEAKAGE MINIMIZING PULSE VALVE MANIFOLD, the disclosure of which is hereby incorporated by reference in its entirety.

### FIELD OF INVENTION

The present disclosure generally relates to fabricating semiconductor devices. Specifically, the present invention relates to pulse valve manifolds used for vapor deposition in semiconductor processing systems.

### BACKGROUND OF THE DISCLOSURE

There are several vapor deposition methods for depositing thin films on surfaces of substrates. These methods include vacuum evaporation deposition, Molecular Beam Epitaxy (MBE), different variants of Chemical Vapor Deposition (CVD) (including low-pressure and organometallic CVD and plasma-enhanced CVD), and Atomic Layer Deposition (ALD).

In an ALD process, one or more substrates with at least one surface to be coated are introduced into a deposition chamber. The substrate is heated to a desired temperature, typically above the condensation temperatures of the selected vapor phase reactants and below their thermal decomposition temperatures. One reactant is capable of reacting with the adsorbed species of a prior reactant to form a desired product on the substrate surface. Two, three or more reactants are provided to the substrate, typically in spatially and temporally separated pulses.

In an example, in a first pulse, a first reactant representing a precursor material is adsorbed largely intact in a self-limiting process on a wafer. The process is self-limiting because the vapor phase precursor cannot react with or adsorb upon the adsorbed portion of the precursor. After any remaining first reactant is removed from the wafer or chamber, the adsorbed precursor material on the substrate reacted with a subsequent reactant pulse to form no more than a single molecular layer of the desired material. The subsequent reactant may, e.g., strip ligands from the adsorbed precursor material to make the surface reactive again, replace ligands and leave additional material for a compound, etc. In an unadulterated ALD process, less than a monolayer is formed per cycle on average due to steric hindrance, whereby the size of the precursor molecules prevent access to adsorption sites on the substrate, which may become available in subsequent cycles. Thicker films are produced through repeated growth cycles until the target thickness is achieved. Growth rate is often provided in terms of angstroms per cycle because in theory the growth depends solely on number of cycles, and has no dependence upon mass supplied or temperature, as long as each pulse is saturative and the temperature is within the ideal ALD temperature window for those reactants (no thermal decomposition and no condensation).

Reactants and temperatures are typically selected to avoid both condensation and thermal decomposition of the reactants during the process, such that chemical reaction is responsible for growth through multiple cycles. However, in certain variations on ALD processing, conditions can be selected to vary growth rates per cycle, possibly beyond one molecular monolayer per cycle, by utilizing hybrid CVD and ALD reaction mechanisms. Other variations maybe allow some amount of spatial and/or temporal overlap between the reactants. In ALD and variations thereof, two, three, four or more reactants can be supplied in sequence in a single cycle, and the content of each cycle can be varied to tailor composition.

During a typical ALD process, the reactant pulses, all of which are in vapor form, are pulsed sequentially into a reaction space (e.g., reaction chamber) with removal steps between reactant pulses to avoid direct interaction between reactants in the vapor phase. For example, inert gas pulses or “purge” pulses can be provided between the pulses of reactants. The inert gas purges the chamber of one reactant pulse before the next reactant pulse to avoid gas phase mixing. To obtain a self-limiting growth, a sufficient amount of each precursor is provided to saturate the substrate. As the growth rate in each cycle of a true ALD process is self-limiting, the rate of growth is proportional to the repetition rate of the reaction sequences rather than to the flux of reactant.

Conventional designs provide a stack of blocks that form a manifold with a long inner bore that is beneficial to more uniform mixing of reactants during vapor deposition. Specifically, using multiple blocks may be beneficial to enable construction of channels to be disposed at various angles inside the manifold. Further, multiple blocks can further provide an extending micing length downstream of when the supply gases are introduced to the bore.

However, such a design requires an extensive number of sealing mechanisms at interfaces. Such a design may result in complicated manufacturing. Further, because of multiple interfaces resultant from stacked manifolds, the changes of leakage between manifolds is high. Multiple parts also may require additional standby time during cleaning. Thus, there is a need for improved pulse valve manifold manufacturing in semiconductor processing devices.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A pulse valve manifold (PVM) assembly is provided. The assembly includes a PVM. The PVM includes a pipe section having an entry inlet to enable a reactant to enter the PVM. The PVM also includes a rectangular block section having a top surface and a bottom surface, wherein the top surface is connected to the pipe section. The PVM further includes a base section connected to the bottom surface. The PVM is formed from two or less manifold parts and is further configured to couple with at least one tombstone manifold block. The PVM assembly includes at least one wetted path formed within the PVM to flow a reactant gas from the entry inlet to an outlet in the base section.

A two-part PVM assembly is provided. The two-part assembly includes a first PVM part comprising a pipe section having an entry inlet to enable a reactant to enter the two-part PVM assembly. The two-part assembly further includes a second PVM part coupled to the first PVM part. The second PVM part has a base outlet to flow the reactant to a showerhead in a semiconductor processing system. The two-part PVM assembly further includes a wetted path defined through first PVM path part and the second PVM part such that the first PVM part is in fluid communication with the second PVM part. The wetted path includes a central path fluidly coupled to the entry inlet. The wetted path also includes a mixing section comprised in the second PVM part, the mixing section fluidly coupled to the central path and the base outlet. Finally, the wetted path also includes a plurality of side inlets fluidly coupled to the central path.

A single part PVM assembly is provided. The single part PVM assembly includes an outer section and an inner section. The outer section includes a pipe section having an entry inlet to enable a reactant to enter the PVM. The outer section includes a pillar-like section having a top surface and a bottom surface, wherein the top surface is connected to the pipe section. The outer section further includes a base section connected to the bottom surface having a base outlet to flow the reactant to a showerhead in a semiconductor processing system. The inner section includes a wetted path defined in the inner section fluidly coupling the entry inlet to the outlet. The outer section includes a plurality of side inlets fluidly coupling to the wetted path.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 illustrates a perspective view of a conventional pulse valve manifold;

FIGS. 2A-2D illustrate one example embodiment of a pulse valve manifold formed from a single part including one embodiment of an internal path in accordance with embodiments described herein;

FIGS. 3A-3D illustrate another example embodiment of a pulse valve manifold formed from a single part including a second embodiment of an internal path in accordance with embodiments described herein.

FIGS. 4A and 4B illustrate perspective view of pulse valve manifold formed from a single part in accordance with embodiments described herein;

FIGS. 5A-5E illustrate one example embodiment of a pulse valve manifold formed from two parts machined together to include one embodiment of an internal path in accordance with embodiments described herein;

FIGS. 6A-6E illustrate a perspective view of a pulse valve manifold formed from two parts machined together to include a second embodiment of an internal path in accordance with embodiments described herein.

FIG. 7 illustrates a perspective view of pulse valve manifold formed from two parts machined together in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any semiconductor processing operation or to the fabrication of any particular semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

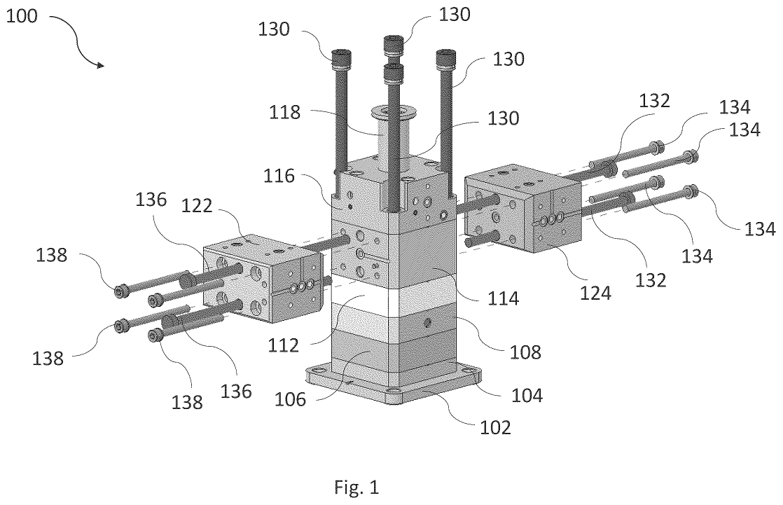

FIG. 1A illustrates a perspective view of a pulse valve manifold (PVM) 100. PVM 100 includes a base 102. Further, PVM 100 includes five manifold blocks 104, 106, 108, 112 and 114 that are configured to stack up on base 102 and may be sealed using one, or preferably, two O-rings at each interface. Thus, eight O-rings are utilized to seal five manifold blocks 104, 106, 108, 112 and 114 in a vertical stack. Further, a sixth block 116 having an inlet pipe 118 is stacked on top of block 114. Block 116 further seals on to block 114 using at least one, two or more O-rings. Further, stacks 104-116 may be aided by bolts 130 to stay aligned in an upright stack.

PVM 100 further includes a first tombstone manifold block 122 and a second tombstone manifold block 124 that are coupled to block 114. These tombstone blocks 122 and 124 can include a gas inlet that allows reactants to flow through to an internal channel. The first tombstone block 122 may be connected at a side of block 114 using bolts 132 and 134 and the second tombstone block 124 may be connected at a side of block 114 using bolts 136 and 138. These blocks 122 and 124 are sealed to block 114 using two or more O-rings. Accordingly, the eight stack PVM 100 utilizes at least fourteen O-rings for sealing.

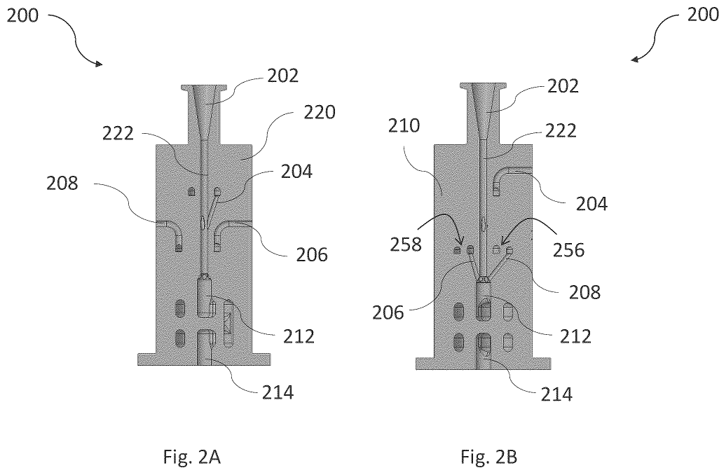

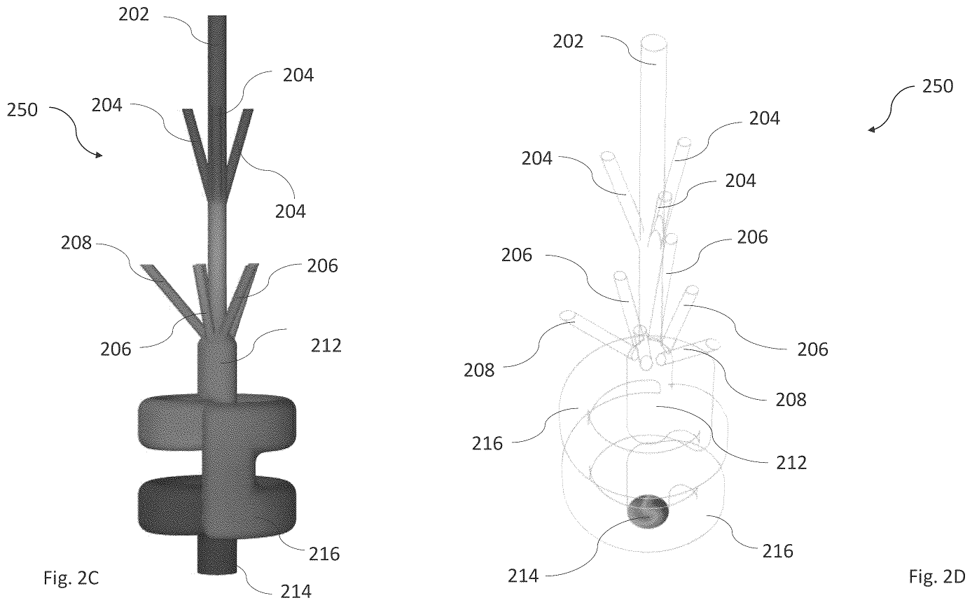

The internal sections of these stacked blocks form an internal channel to mix the reactants together prior to flowing through the showerhead of the semiconductor processing system and deposition on the substrate. This internal channel may include any previous conventional channels/paths that may have been utilized for reactant mixing. For example, any conventional axial, helical, spiral, C-channel or a combination thereof may be utilized. However, the number of interfaces in such a design increase a chance of leakage between the stacked manifold blocks. Such a design further increases standby time for cleaning and may results in increased costs for parts replacement. Accordingly, the present application provides example embodiments in FIGS. 2-7 providing an improved pulse valve manifold that reduces the number of parts required in manufacturing a PVM.

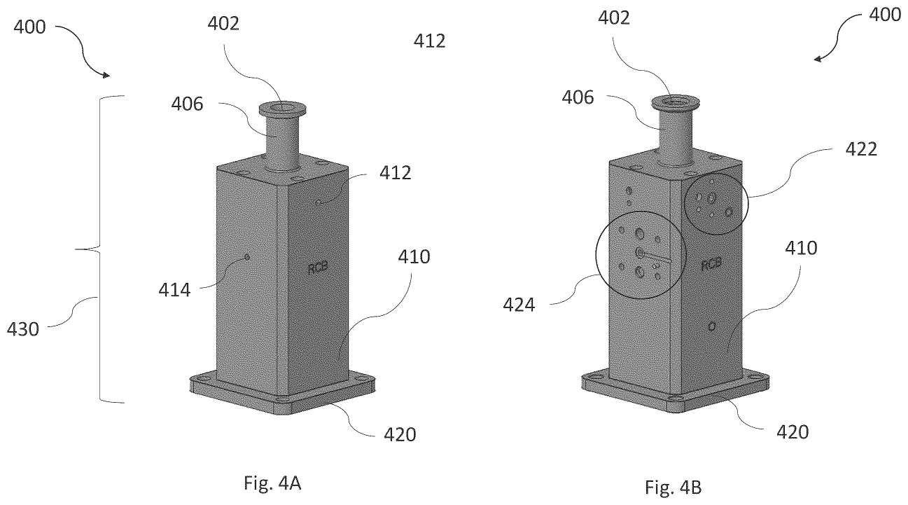

Referring now to FIG. 4A, a perspective view of one exemplary PVM 400 is provided. As shown in FIG. 4A, pipe 406, vertical block 410 and base 420 are a single part 430 (unlike stacked blocks as shown in FIG. 1). In exemplary embodiments, additive manufacturing (such as 3D printing) may be used to form pipe 406, vertical block 410 and base 420. Accordingly, pipe 406, vertical block 410 and base 420 form a single part 430.

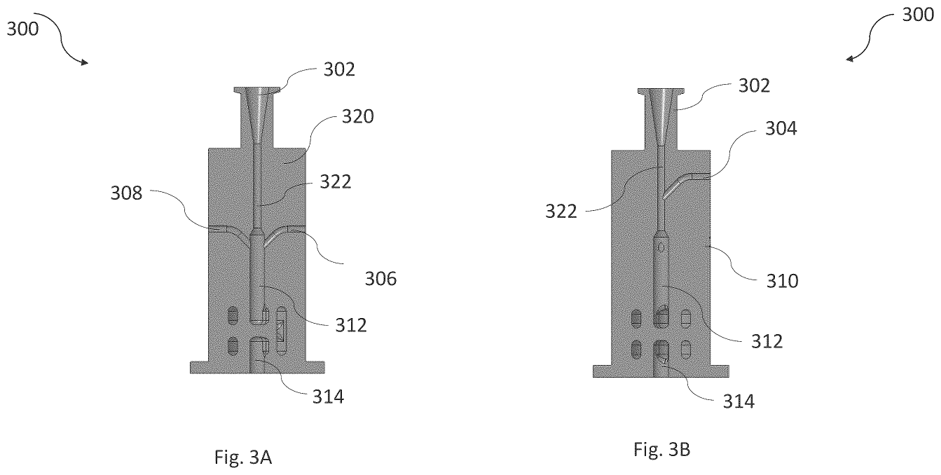

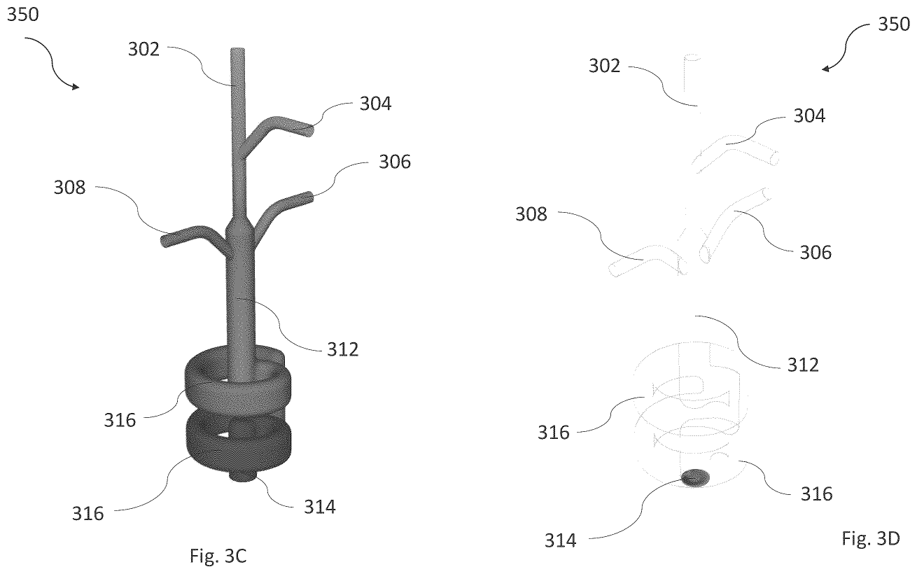

Tombstone manifold blocks (such as 122 and 124) are not formed as section of the single part 430. Thus, in exemplary embodiments, additional interfaces 422 and 424 may be machined in to allow tombstone manifold blocks to couple and mount with part 430 (see FIG. 4B). In exemplary embodiments, these tombstone manifold blocks may be sealed to part 430 using a plurality of C-seals. In further exemplary embodiments, seven C-seals may be used for sealing with part 430 to form PVM 400. However, the internal path for the reactants to flow and mix prior to deposition may differ in different embodiments. FIGS. 2A-2D and 3A-3D provide various embodiments of PVM 400 with different internal reactant paths.

Referring now to FIGS. 2A-2D, multiple view of PVM 200 are illustrated. PVM 200 may be one exemplary embodiment of a single part 430 as described with respect to FIG. 4. Specifically, FIGS. 2A-2D illustrate an internal path that the reactants flow through to mix uniformly prior to deposition. FIG. 2A provides a cross section of PVM 200 as viewed at a first side (for example, front view) and FIG. 2B provides a cross section of PVM 200 as viewed at a different side (for example, back or side view). FIGS. 2C and 2D provide a perspective view of a path 250 formed internally in PVM 200.

PVM 200 is formed to include an inlet 202 that provides an entry point for one or more reactant gas to enter internal path 250. In exemplary embodiment, inlet 202 may extend into a narrow central path 222. PVM 200 may further include a first side inlet 204, a second side inlet 206 and a third side inlet 208. In exemplary embodiments, inlets 204, 206 and 208 form a C-channel (such as C-channel 256 formed from inlet 206 and C-channel 258 from inlet 208) that allows the reactant(s) to flow along the respective C-channel prior to flowing back into the mid-central path 212. As shown in FIGS. 2C and 2D, in exemplary embodiments, the reactants may flow along a helical path 216 to allow the reactants to mix thoroughly. In further exemplary embodiments, the mix may then flow out through outlet 214 for uniform deposition on a substrate.

Referring now to FIGS. 3A-3D, multiple view of PVM 300 are illustrated. PVM 300 may be one exemplary embodiment of a single part 430 as described with respect to FIG. 4. Specifically, FIGS. 3A-3D illustrate an internal path that the reactants flow through to mix uniformly prior to deposition. FIG. 3A provides a cross section of PVM 300 as viewed at a first side (for example, front view) and FIG. 3B provides a cross section of PVM 300 as viewed at a different side (for example, back or side view). FIGS. 3C and 3D provide a perspective view of a path 350 formed internally in PVM 300.

PVM 300 is formed to include an inlet 302 that provides an entry point for one or more reactant gas to enter internal path 350. In exemplary embodiment, inlet 302 may extend into a narrow central path 322. PVM 300 may further include a first side inlet 304, a second side inlet 306 and a third side inlet 308. Unlike PVM 200, reactants flowing through inlets 304, 306 and 308 flow directly into the central path 312. As shown in FIGS. 3C and 3D, in exemplary embodiments, the reactants may then flow along a helical path 316 to allow the reactants to mix thoroughly. In further exemplary embodiments, the mix may then flow out through outlet 314 for uniform deposition on a substrate.

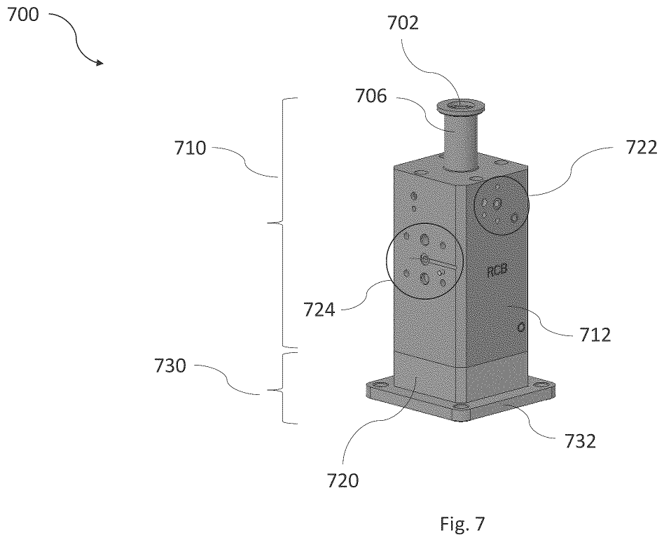

Referring now to FIG. 7, a perspective view of one exemplary PVM 700 is provided. As shown in FIG. 7A, pipe 706 (including an inlet 702) and a first vertical section 712 form a top part 710. Base 732 and a second vertical section 720 from a bottom part 730. These two parts, top part 710 and bottom part 730 may be machined together to form PVM 700. Further, the two parts may be sealed by utilizing one O-ring.

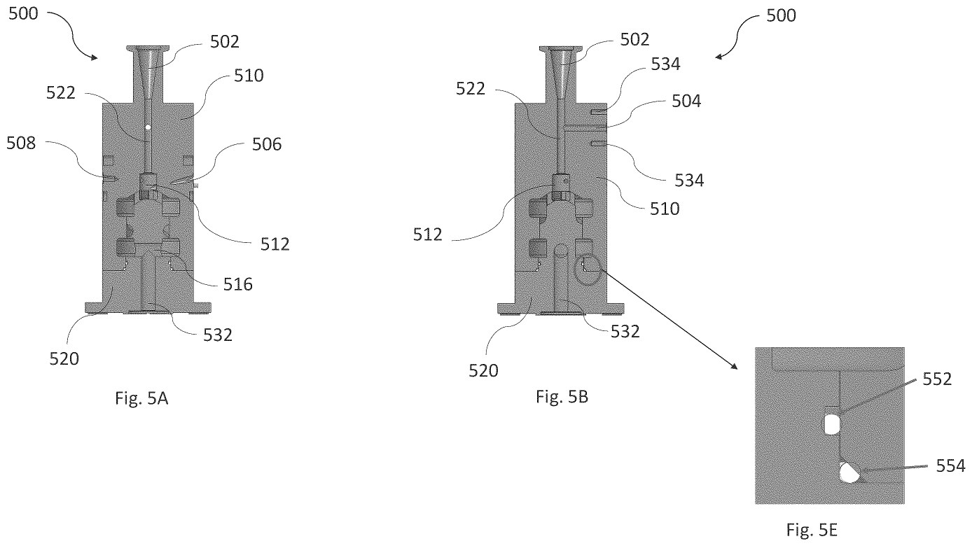

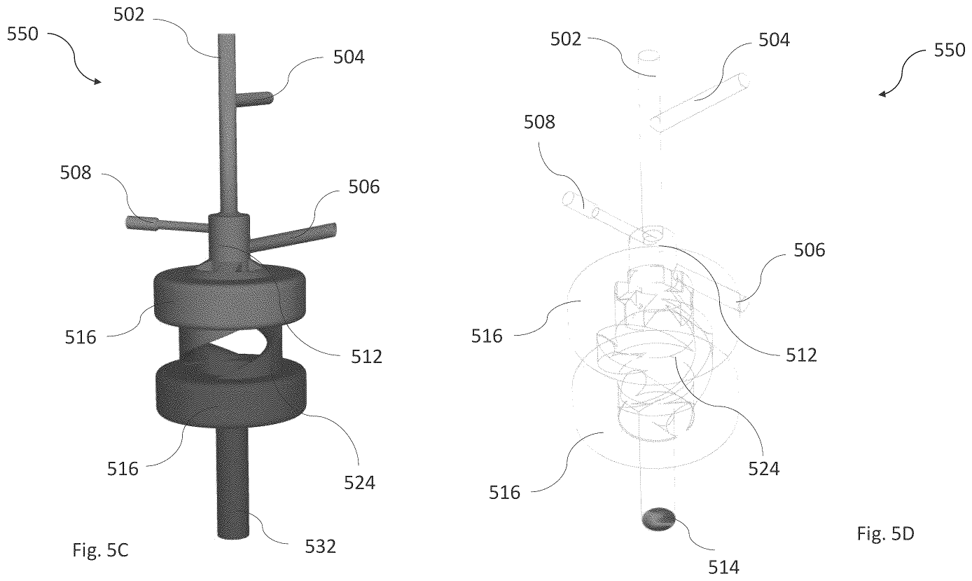

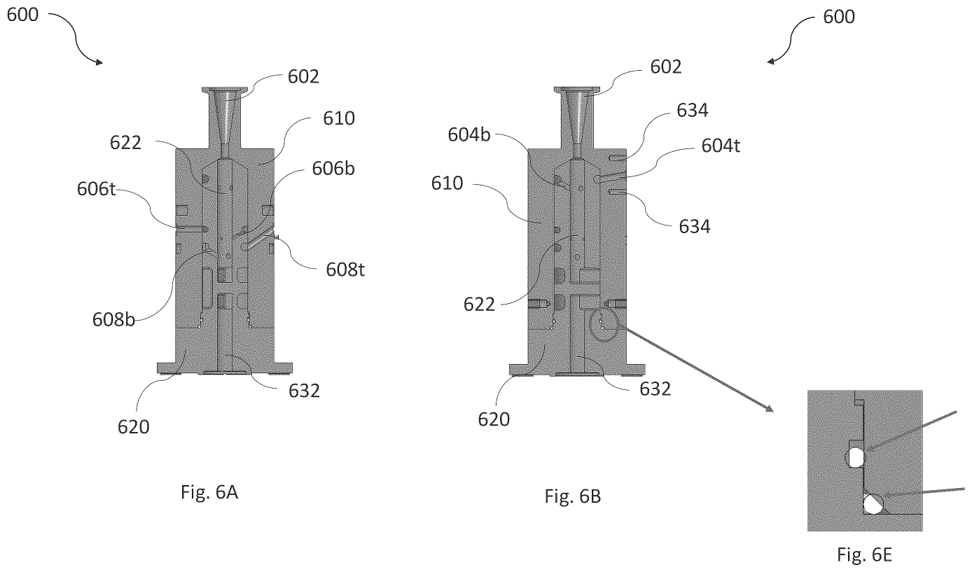

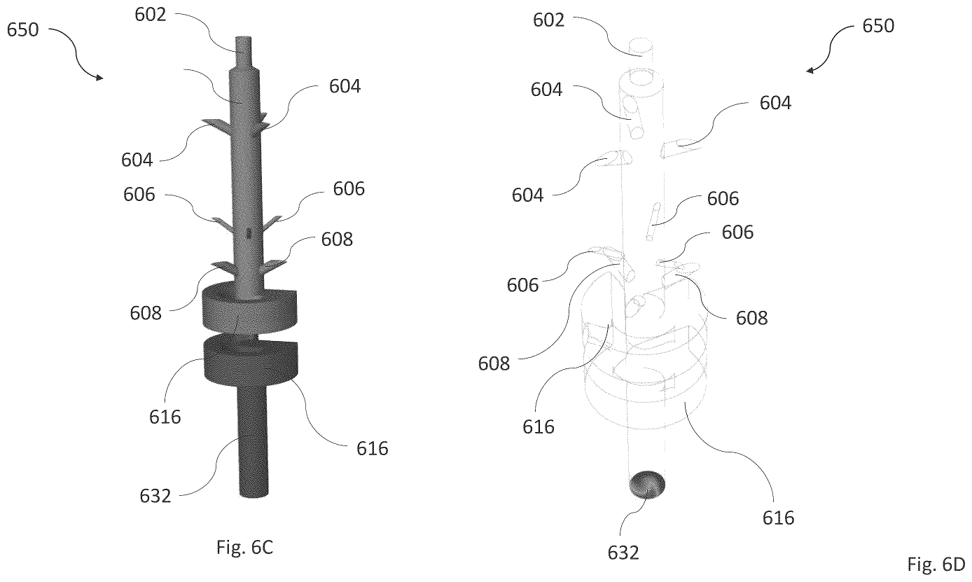

Further, PVM 700 is configured to mount tombstone manifold blocks (such as 122 and 124). Thus, in exemplary embodiments, interfaces 722 and 724 may be machined in to allow tombstone manifold blocks to couple and mount with top part 710 of PVM 700. In exemplary embodiments, these tombstone manifold blocks may be sealed to top part 710 using a plurality of C-seals. In further exemplary embodiments, seven C-seals may be used for sealing with top part 710. Accordingly, in exemplary embodiments, the two-part machined PVM 700 may include seven C-seals and one O-ring for sealing. However, the internal path for the reactants to flow and mix prior to deposition may differ in different embodiments. FIGS. 5A-5E and 6A-6E provide various embodiments of PVM 700 with different internal reactant paths.

Referring now to FIGS. 5A-5E, multiple views of PVM 500 are illustrated. PVM 500 may be one exemplary embodiment of two-part machined PVM 700 as described with respect to FIG. 7. Specifically, FIGS. 5A-5E illustrate an internal path that the reactants flow through to mix uniformly prior to deposition. FIG. 5A provides a cross section of PVM 500 as viewed at a first side (for example, front view) and FIG. 5B provides a cross section of PVM 500 as viewed at a different side (for example, back or side view). FIGS. 5C and 5D provide a perspective view of a path 550 formed internally in PVM 500. FIG. 5E provides an expanded view of sealing between top part 510 and bottom part 520.

PVM 500 is formed to include an inlet 502 that provides an entry point for one or more reactant gas to enter internal path 550. In exemplary embodiment, inlet 502 may extend into a narrow central path 522. PVM 500 may further include a first side inlet 504, a second side inlet 506 and a third side inlet 508. Reactants flowing through inlets 504, 506 and 508 flow directly into the mid-central path 512. As shown in FIGS. 5C and 5D, in exemplary embodiments, the reactants may then flow along a spiral path 516 to allow the reactants to mix thoroughly. In further exemplary embodiments, the mix may then flow through bottom central path 532 and then out through outlet 514 for uniform deposition on a substrate.

Accordingly, in the exemplary embodiments shown in FIGS. 5A and 5B, top part 510 includes side inlets 504, 506 and 508 and bottom part 520 includes the spiral path 516 and bottom central path 532 including outlet 514. The two parts 510 and 520 may be aligned together to provide a smooth transition from the side inlets 504, 506 and 508 to spiral path 516. As shown in FIG. 5E, top part 510 couples with bottom part 520 at mid-central path 512. As shown in FIGS. 5A and 5B, top part 510 is recessed to allow the protruding bottom part 520 to fit in with the recessed top part 510. Top part 510 and bottom part 520 may be sealed at a straight edge as shown in FIG. 5E. In exemplary embodiments, a first O-ring 552 may be used as a seal. In further exemplary embodiments a second O-ring 554 may be used as a seal.

Referring now to FIGS. 6A-6E, multiple views of PVM 600 are illustrated. PVM 600 may be one exemplary embodiment of two-part machined PVM 700 as described with respect to FIG. 7. Specifically, FIGS. 6A-6E illustrate an internal path that the reactants flow through to mix uniformly prior to deposition. FIG. 6A provides a cross section of PVM 600 as viewed at a first side (for example, front view) and FIG. 6B provides a cross section of PVM 600 as viewed at a different side (for example, back or side view). FIGS. 6C and 6D provide a perspective view of a path 650 formed internally in PVM 600. FIG. 6E provides an expanded view of sealing between top part 610 and bottom part 620.

PVM 600 is formed to include an inlet 602 that provides an entry point for one or more reactant gas to enter internal path 650. In exemplary embodiment, inlet 602 may extend into a narrow central path 622. PVM 600 may further include a first side inlet 604, a second side inlet 606 and a third side inlet 608. In exemplary embodiments, inlets 604, 606 and 608 flow to the central path 622. As shown in FIG. 6, inlet 604t begins in top part 610 and flows into central path 622 via inlet 604b in bottom part 620. Similarly, inlets 606t, 608t begin in top part 610 and flow into central path 622 via inlet 606b, 608b, in bottom part 620. In exemplary embodiments, the reactants then flow along a helical path 616 to allow the reactants to mix thoroughly. In further exemplary embodiments, the mix may then flow through bottom central path 632 and then out through outlet 614 for uniform deposition on a substrate.

Accordingly, the two parts 610 and 620 may be aligned together to provide a smooth transition from the side inlets 604, 606 and 608 to helical path 616. In exemplary embodiments, all of the central path 622 and the entirety of helical path 616 is included in bottom part 620. As shown in FIG. 6E, top part 610 couples with bottom part 620 as inlet 602 ends and central path 622 begins. As shown in FIGS. 6A and 6B, top part 610 is recessed to allow the protruding bottom part 620 to fit in with the recessed top part 610. Top part 610 and bottom part 620 may be sealed at a straight edge as shown in FIG. 6E. In exemplary embodiments, a first O-ring 652 may be used as a seal. In further exemplary embodiments a second O-ring 654 may be used as a seal. In exemplary embodiments, top part 610 further includes a cavity 634 to allow tombstone manifold block to be coupled to the PVM 600.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A pulse valve manifold (PVM) assembly comprises:
a PVM comprising:
a pipe section having an entry inlet to enable a reactant to enter the PVM;
a rectangular block section having a top surface and a bottom surface, wherein the top surface is connected to the pipe section; and
a base section connected to the bottom surface;
wherein the PVM is formed from two or less manifold parts, and wherein the PVM is further configured to couple with at least one tombstone manifold block;
at least one wetted path formed within the PVM to flow a reactant gas from the entry inlet to an outlet in the base section.

2. The PVM assembly of claim 1, wherein the PVM is a single piece.

3. The PVM assembly of claim 2, wherein the PVM is formed using a process of additive manufacturing.

4. The PVM assembly of claim 1, wherein the wetted path comprises at least one helical channel.

5. The PVM assembly of claim 1, wherein the wetted path comprises at least one C-channel.

6. The PVM assembly of claim 1, wherein the wetted path comprises at least one spiral channel.

7. The PVM assembly of claim 1, further comprising:
a plurality of tombstone manifold blocks configured to couple with the PVM; and
a plurality of C-seals sealing the at least one tombstone manifold block with the PVM.

8. The PVM assembly of claim 7, wherein the plurality of C-seals is equal to or less than seven C-seals.

9. The PVM assembly of claim 1, wherein the wetted path comprises:
a central path fluidly coupled to the entry inlet; and
a plurality of side inlets, each of the plurality of side inlets configured to fluidly couple to at least one of the plurality of tombstone manifold blocks, wherein the plurality of inlets further fluidly coupled to the central path;
a mixing channel comprising at least one of a helical channel or a spiral channel; and
the outlet in the base section, wherein the outlet is fluidly coupled to the mixing channel.

10. The PVM assembly of claim 1, wherein the PVM further comprises:
a first PVM part; and a
a second PVM part coupled to the first PVM part, wherein the wetted path is defined through the first PVM part and the second PVM part such that the first PVM part is in fluid communication with the second PVM part; and
wherein the first PVM part is sealed to the second PVM part via two or less O-ring seals.

11. The PVM assembly of claim 10, wherein the first PVM part is sealed to the second PVM part via a single O-ring seal.

12. The PVM assembly of claim 10,
wherein the rectangular block section comprises a top rectangular section and a bottom rectangular section,
wherein the first PVM part comprises the pipe section and the top rectangular section,
wherein the second PVM part comprises the bottom rectangular section and the base section,
wherein the wetted path is further defined through the top rectangular section and the bottom rectangular section, wherein the top rectangular section and the bottom rectangular section are in fluid connection.

13. The PVM assembly of claim 1, wherein the PVM assembly is coupled to a showerhead of a semiconductor processing system.

14. A two part PVM assembly comprises:
a first PVM part comprising a pipe section having an entry inlet to enable a reactant to enter the two-part PVM assembly;
a second PVM part coupled to the first PVM part, the second PVM part having a base outlet to flow the reactant to a showerhead in a semiconductor processing system;
a wetted path defined through first PVM path part and the second PVM part such that the first PVM part is in fluid communication with the second PVM part, wherein the wetted path comprises:
a central path fluidly coupled to the entry inlet;
a mixing section comprised in the second PVM part, the mixing section fluidly coupled to the central path and the base outlet; and
a plurality of side inlets fluidly coupled to the central path.

15. The two part PVM assembly of claim 14, wherein each of the plurality of side inlets is defined within both the first PVM part and the second PVM part.

16. The two part PVM assembly of claim 14, wherein the mixing section comprises a helical section, and wherein the second PVM part comprises the central path.

17. The two part PVM assembly of claim 14, wherein the mixing section comprises a spiral section.

18. A single part PVM comprising:
an outer section comprising:
a pipe section having an entry inlet to enable a reactant to enter the single part PVM;
a pillar-like section having a top surface and a bottom surface, wherein the top surface is connected to the pipe section; and
a base section connected to the bottom surface having a base outlet to flow the reactant to a showerhead in a semiconductor processing system; and
an inner section comprising:
a wetted path defined in the inner section fluidly coupling the entry inlet to an outlet; and
a plurality of side inlets fluidly coupling to the wetted path.

19. The single part PVM of claim 18, wherein the wetted path further comprises: a central path, wherein the plurality of side inlets are fluidly coupled to the central path, and a helical channel, wherein the helical channel is fluidly coupled to the central path and the base outlet.

20. The single part PVM of claim 19, wherein the wetted path further comprises a C-channel, wherein the plurality of side inlets are fluidly coupled to the C-channel, and wherein the C-channel is fluidly coupled to the central path.
